(19) United States
(12) Patent Application Publication
(10) Pub. No.: US 2006/0186415 A1
(43) Pub. Date: Aug. 24, 2006

(54) Thin film semiconductor device, method of manufacturing the same, and display

(76) Inventor: Akihiko Asano, Kanagawa (JP)

Correspondence Address: David R. Metzger;SONNENSCHEIN NATH & ROSENTHAL, Sears Tower, Wacker Drive Station, P.O. Box 061080, Chicago, IL, 60606-1080, US

(21) Appl. No.: 11/358,845

(22) Filed: Feb. 21, 2006

(30) Foreign Application Priority Data
Feb. 24, 2005 (JP) P2005-049716

(51) Int. Cl. H01L 29/04

(52) U.S. Cl. 257/72

(57) ABSTRACT

Irradiation with laser light is conducted, whereby an external region of a semiconductor thin film located on the outer side relative to a pattern of a light absorbing layer is thermally melted, and the light absorbing layer is heated, without melting an internal region of the semiconductor thin film located on the inner side relative to the pattern. Next, the molten semiconductor thin film is cooled, whereby microcrystal grains are produced in the vicinity of the boundary between the external region and the internal region. Further, a first lateral crystal growth progresses from the boundary toward the outer side with the microcrystals as nuclei, whereby polycrystal grains are produced in an area of the external region. Finally, heat is transferred from the heated light absorbing layer to the semiconductor thin film, whereby the internal region is melted, and thereafter a second lateral crystal growth progresses from the boundary toward the inner side with the polycrystal grains as nuclei, whereby further enlarged polycrystal grains are produced in the internal region.

### CROSS REFERENCES TO RELATED APPLICATIONS

The present invention contains subject matter related to Japanese Patent Application JP 2005-049716 filed with the Japanese Patent Office on Feb. 24, 2005, the entire contents of which being incorporated herein by reference.

### BACKGROUND OF THE INVENTION

The present invention relates to a thin film semiconductor device and a method of manufacturing the same, and to an active matrix type display configured by use of the thin film semiconductor device. Particularly, the invention relates to a semiconductor thin film crystallizing technology for forming device regions of a thin film semiconductor device. More particularly, the invention relates to a lateral crystal growth technology for creating a temperature difference between different regions of a semiconductor thin film by laser annealing and inducing crystal growth in the film plane direction (lateral direction) by utilizing the temperature difference.

A thin film semiconductor device has thin film transistors as main component devices. The thin film transistor uses a semiconductor thin film as an active layer. As the semiconductor thin film, for example, a silicon film is generally used. In recent years, a technology of forming a polycrystalline silicon film on an inexpensive glass substrate as an active layer of a thin film transistor has been developed progressingly.

As a technology for forming a polycrystalline silicon film on a glass substrate at a low temperature, there has been developed a crystallizing technology based on irradiation with laser light. The crystallization by irradiation with laser light (hereinafter referred to as “laser annealing” in some cases) is a technology in which the energy of laser light is absorbed into an amorphous silicon film, whereby only the film is instantaneously melted, and recrystallization is achieved during the cooling process.

Recently, a technology of obtaining a polycrystalline silicon film with a high crystallinity by use of a continuously oscillated laser light has been publicly reported. In this technology, an amorphous silicon film is scanned with a continuously oscillated laser beam so that a solid-liquid interface in the semiconductor thin film is moved in a lateral direction, whereby a temperature difference is created in the film, and lateral crystal growth is induced in the silicon film by utilizing the temperature difference. However, the process margin of this technology is narrow in that, if the scanning speed is low, the film itself is lost through bumping, and, if the scanning speed is high, the speed would exceed the moving velocity of the solid-liquid interface, resulting in an insufficient lateral crystal growth.

A crystal growth technology utilizing a pulsedly oscillated laser beam in place of the continuously oscillated laser beam has also been developed, as described for example in Japanese Patent Laid-open No. 2003-318108 (hereinafter referred to as Patent Document 1). In the technology as described in Patent Document 1, an amorphous silicon film is formed on a substrate, and a metallic film is formed on a part of the amorphous silicon film. A first irradiation with laser beam from the upper side of the amorphous silicon film is conducted using the metallic film as a mask, whereby the part, other than the part masked by the metallic film, of the amorphous silicon film is crystallized. Thereafter, the metallic film is removed, and a second irradiation with laser beam from the upper side of the amorphous silicon film is conducted, to crystallize a part of the amorphous silicon. The polycrystalline silicon film crystallized by the second irradiation with laser beam is used as a channel region of a thin film transistor.

### SUMMARY OF THE INVENTION

However, in the crystallization technology disclosed in Patent Document 1, the irradiation with laser beam is carried out two times, and the metallic film mask used in the first irradiation with laser beam is removed, before carrying out the second irradiation with laser beam. Therefore, the process for crystallization is complicated, which is undesirable from the viewpoint of productivity. In addition, since the irradiation with laser beam is carried out dividedly in two runs, it is difficult for a uniform lateral crystal growth to take place, and it is difficult to obtain a good crystallinity.

Thus, there is a need to induce lateral crystal growth by a single run of irradiation with laser beam and thereby to form a semiconductor thin film having a uniform crystal structure. In order to fulfill the above need, according to one embodiment of the present invention, there is provided a method of manufacturing a thin film semiconductor device, including a light absorbing layer forming step for forming a light absorbing layer on the face side of a transparent substrate, a patterning step for patterning the light absorbing layer into a predetermined shape, an insulation film forming step for covering the patterned light absorbing layer with an insulation film, a semiconductor thin film forming step for forming a semiconductor thin film on the insulation film, and a laser annealing step for irradiating the substrate with laser light pulsedly oscillated from the back side of the substrate so as to crystallize the semiconductor thin film, wherein the laser annealing step includes: a first process in which an external region of the semiconductor thin film located on the outer side relative to the pattern of the light absorbing layer is thermally melted, and the light absorbing layer is heated, without melting an internal region of the semiconductor thin film located on the inner side relative to the pattern of said light absorbing layer; a second process in which the molten semiconductor thin film is cooled and microcrystal grains are produced in the vicinity of the boundary between the external region and the internal region; a third process in which a first lateral growth progresses from the boundary between the external region and the internal region toward the outer side with the microcrystal grains as nuclei so that polycrystal grains greater than the microcrystal grains are produced in the area of the external region adjacent to the boundary; and a fourth process in which heat is transferred from the heated light absorbing layer to the semiconductor thin film through the insulation film, whereby the internal region is melted, and thereafter a second lateral growth progresses from the boundary toward the inner side with the polycrystal grains as nuclei so that further enlarged polycrystal grains are produced in the internal region.

According to another embodiment of the present invention, there is provided a method of manufacturing a thin film semiconductor device, including a semiconductor thin film forming step for forming a semiconductor thin film on a substrate, an insulation film forming step for forming an insulation film thereon, a light absorbing layer forming step for forming a light absorbing layer on the upper side of the semiconductor thin film, with the insulation film therebetween, a patterning step for pattering the light absorbing layer into a predetermined shape, and a laser annealing step for irradiating the substrate with laser light pulsedly oscillated from the upper side of the substrate so as to crystallize the semiconductor thin film, wherein the laser annealing step includes: a first process in which an external region of the semiconductor thin film located on the outer side relative to the pattern of the light absorbing layer is thermally melted, and the light absorbing layer is heated, without melting an internal region of the semiconductor thin film located on the inner side relative to the pattern of the light absorbing layer; a second process in which the molten semiconductor thin film is cooled and microcrystal grains are produced in the vicinity of the boundary between the external region and the internal region; a third process in which a first lateral growth progresses from the boundary between the external region and the internal region toward the outer side with the microcrystal grains as nuclei so that polycrystal grains greater than the microcrystal grains are produced in the area of the external region adjacent to the boundary; and a fourth process in which heat is transferred from the heated light absorbing layer to the semiconductor thin film through the insulation film, whereby the internal region is melted, and thereafter a second lateral growth progresses from the boundary toward the inner side with the polycrystal grains as nuclei so that further enlarged polycrystal grains are produced in the internal region.

Preferably, the laser annealing step includes irradiating the substrate with laser light having a wavelength range of from 520 to 540 nm. The laser annealing step may include irradiating the substrate with the pulsedly oscillated laser light while scanning in such a range that irradiated regions overlap with each other. Preferably, the light absorbing layer forming step includes forming the light absorbing layer by use of a conductive film, and the patterning step includes pattering the conductive material so as to produce a wiring including a gate electrode. In this case, preferably, a high melting point metal or an alloy or silicide containing a high melting point metal as a constituent thereof is used as the conductive material for forming the light absorbing layer.

According to a further embodiment of the present invention, there is provided a thin film semiconductor device including an insulating substrate provided integratedly with thin film transistors, wherein each of the thin film transistors includes a semiconductor thin film and a gate electrode laminated, with a gate insulation film therebetween; the semiconductor thin film includes a channel region overlapping with the gate electrode, and a source region and a drain region which are located respectively on both sides of the channel region; the semiconductor thin film is a polycrystalline layer crystallized by laser annealing, and is divided along the boundary of a predetermined pattern into an internal region and an external region; the external region has a first lateral growth region containing polycrystal grains laterally grown from the boundary toward the outer side by the laser annealing; the internal region has a second lateral growth region containing polycrystal grains laterally grown from the boundary toward the inner side with the polycrystalline contained in the first lateral growth region as nuclei; and the channel region is formed in the second lateral growth region.

Preferably, the semiconductor thin film is a polycrystalline layer crystallized by the laser annealing conducted by irradiation with laser light through a light absorbing layer formed in a predetermined pattern, and is formed through: a first process in which the external region located on the outer side relative to the pattern of the light absorbing layer is thermally melted, and the light absorbing layer is heated, without melting the internal region located on the inner side relative to the pattern of the light absorbing layer; a second process in which the molten semiconductor thin film is cooled and microcrystal grains are produced in the vicinity of the boundary between the external region and the internal region; a third process in which a first lateral growth progresses from the boundary between the external region and the internal region toward the outer side with the microcrystal grains as nuclei so that polycrystal grains greater than the microcrystal grains are produced in the area of the external region adjacent to the boundary; and a fourth process in which heat is transferred from the heated light absorbing layer to the semiconductor thin film through the gate insulation film, whereby the internal region is melted, and thereafter a second lateral growth progresses from the boundary toward the inner side with the polycrystal grains as nuclei so that further enlarged polycrystal grains are produced in the internal region. In addition, preferably, the light absorbing layer used in the laser annealing includes a conductive material, and the gate electrode is formed from the conductive material either directly or through a processing. The gate electrode may be formed by using a high melting point metal or an alloy or silicide containing a high melting point metal as a constituent thereof, as the conductive material. Preferably, the source region and the drain region range into at least a part of the first lateral growth region. The first lateral growth region in which the source region and the drain region are formed may range over a distance of at least 2 μm from the boundary toward the outer side. Preferably, the thin film transistor includes an LDD region lower in impurity concentration than the drain region between the channel region and at least the drain region, and the LDD region is formed in the first lateral growth region or the second lateral growth region.

According to yet another embodiment of the present invention, there is provided a display including an insulating substrate provided integratedly with pixels and thin film transistors for driving the pixels, wherein each of the thin film transistors includes a semiconductor thin film and a gate electrode laminated, with a gate insulation film therebetween; the semiconductor thin film includes a channel region overlapping with the gate electrode, and a source region and a drain region which are located respectively on both sides of the channel region; the semiconductor thin film is a polycrystalline layer crystallized by laser annealing, and is divided along the boundary of a predetermined pattern into an internal region and an external region; the external region has a first lateral growth region containing polycrystal grains laterally grown from the boundary toward the outer side by the laser annealing; the internal region has a second lateral growth region containing polycrystal grains laterally grown from the boundary toward the inner side with the polycrystal grains contained in the first lateral growth region as nuclei; and the channel region is formed in the second lateral growth region.

Preferably, the semiconductor thin film is a polycrystalline layer crystallized by the laser annealing conducted by irradiation with laser light through a light absorbing layer formed in a predetermined pattern, and is formed through: a first process in which the external region located on the outer side relative to the pattern of the light absorbing layer is thermally melted, and the light absorbing layer is heated, without melting the internal region located on the inner side relative to the pattern of the light absorbing layer; a second process in which the molten semiconductor thin film is cooled and microcrystal grains are produced in the vicinity of the boundary between the external region and the internal region; a third process in which a first lateral growth progresses from the boundary between the external region and the internal region toward the outer side with the microcrystal grains as nuclei so that polycrystal grains greater than the microcrystal grains are produced in the area of the external region adjacent to the boundary; and a fourth process in which heat is transferred from the heated light absorbing layer to the semiconductor thin film through the gate insulation film, whereby the internal region is melted, and thereafter a second lateral growth progresses from the boundary toward the inner side with the polycrystal grains as nuclei so that further enlarged polycrystal grains are produced in the internal region. Besides, each of the pixels may include an organic electroluminescence device. Alternatively, each of the pixels may include a pixel electrode connected to the thin film transistor, a counter electrode opposed to the pixel electrode, and a liquid crystal held between the electrodes.

In accordance with the present invention, the pattern of the light absorbing layer used for the gate electrode or the like is formed on the amorphous semiconductor thin film, to divide the semiconductor thin film into the internal region covered with the pattern and the external region surrounding the internal region. With the pattern of the light absorbing layer as a mask, irradiation with laser light is carried out once so as to achieve uniform crystallization. By the one run of irradiation with laser light, the lateral crystal growth in the external region and the lateral crystal growth in the internal region can be performed sequentially, with a delay time of not more than 10 μs. In the present invention, the generation of a delay from the external region which is melted immediately upon direct irradiation with the laser light is tactfully utilized for melting the internal region by heat transfer to the semiconductor thin film after the light absorbing layer is heated by irradiation with the laser light. Since it suffices to carry out only one run of irradiation with laser light, the laser light irradiation apparatus itself may be simple in configuration, and the throughput is remarkably enhanced from the viewpoint of process also.

The melting of the internal region covered with the pattern of the light absorbing layer would need a higher laser energy density (area density) than that for the melting of the semiconductor thin film in the external region. The reason lies in that the light absorbing layer to be used as the mask is formed of a high melting point metal or the like, which has a high heat capacity, and the melting thereof needs a greater amount of heat accordingly. An additional reason lies in that, in the case of a bottom gate structure, the transfer of heat to the semiconductor thin film is accompanied by dissipation of heat into the glass substrate. For ensuring that the light absorbing layer is sufficiently heated by one run of irradiation with laser light and not any excessive thermal energy is applied to the external region of the semiconductor thin film, it is effective to use laser light having a wavelength range of from 520 to 540 nm. The laser light with this green color wavelength is the so-called green laser, which is characterized by a lower absorptivity in absorption into a silicon film, as compared with UV excimer laser. The green laser is absorbed by the silicon film only partly, which makes it possible to heat the pattern of the light absorbing layer in a high energy density and, on the other hand, to heat the other external region in a low energy density. For example, at room temperature, only 5 to 10% of green laser is absorbed by a silicon film. With the green laser used, it is possible to first induce the first lateral crystal growth in the external region and thereafter to induce the second lateral crystal growth in the internal region, with a predetermined delay.

In accordance with the manufacturing method of the present invention, the lateral crystal growth is controlled according to the pattern of the light absorbing layer which is formed prior to the laser annealing. This makes it possible to control the size and position of the polycrystalline silicon grain boundary in the internal region, whereby uniformity is enhanced remarkably. With this internal region used for the channel region of the thin film transistor, it is possible to conspicuously improve the characteristics of the thin film transistor. In addition, since crystallization is tactfully carried out by one run of irradiation with laser light in the present invention, the processing rate is enhanced by a simply calculated factor of about 10 to 20 times, as compared with the case where about 10 to 20 runs of irradiation are carried out per one location according to the related art. Furthermore, since the size and position of the crystal grains are little changed even in the case where the irradiated regions partly overlap with each other, the substrate can be irradiated with pulsedly oscillated laser light while scanning in such a range that the irradiated regions partly overlap with each other. For example, crystallinity is little changed even when irradiation with line beams having a longitudinal irradiation region shape is conducted so that the line beams overlap with each other in the major axis direction. Therefore, when the irradiation is conducted so that the line beams partly overlap with each other, a device having a width exceeding the width of the line beam can uniformly be treated to be crystallized.

### BRIEF DESCRIPTION OF THE DRAWINGS

FIGS. 1A to 1C are schematic diagrams showing the basic configuration of the method of manufacturing a thin film semiconductor device according to the present invention.

FIG. 2 shows an optical microphotograph of a thin film semiconductor device manufactured according to the present invention.

FIG. 3 shows an optical microphotograph of a reference example.

FIGS. 4A and 4B are step diagrams showing a first embodiment of the method of manufacturing a thin film semiconductor device according to the present invention.

FIGS. 5C and 5D also are step diagrams showing the first embodiment.

FIGS. 6A and 6B are step diagrams showing a second embodiment of the method of manufacturing a thin film semiconductor device according to the present invention.

FIGS. 7C and 7D also are step diagrams showing the second embodiment.

FIG. 8 is a schematic plan diagram showing the crystal structure of a thin film transistor manufactured according to the present invention.

FIG. 9 also is a schematic plan diagram showing the crystal structure.

FIG. 10 is a schematic sectional diagram showing an example of the display according to the present invention.

### DETAILED DESCRIPTION OF THE PREFERRED EMBODIMENTS

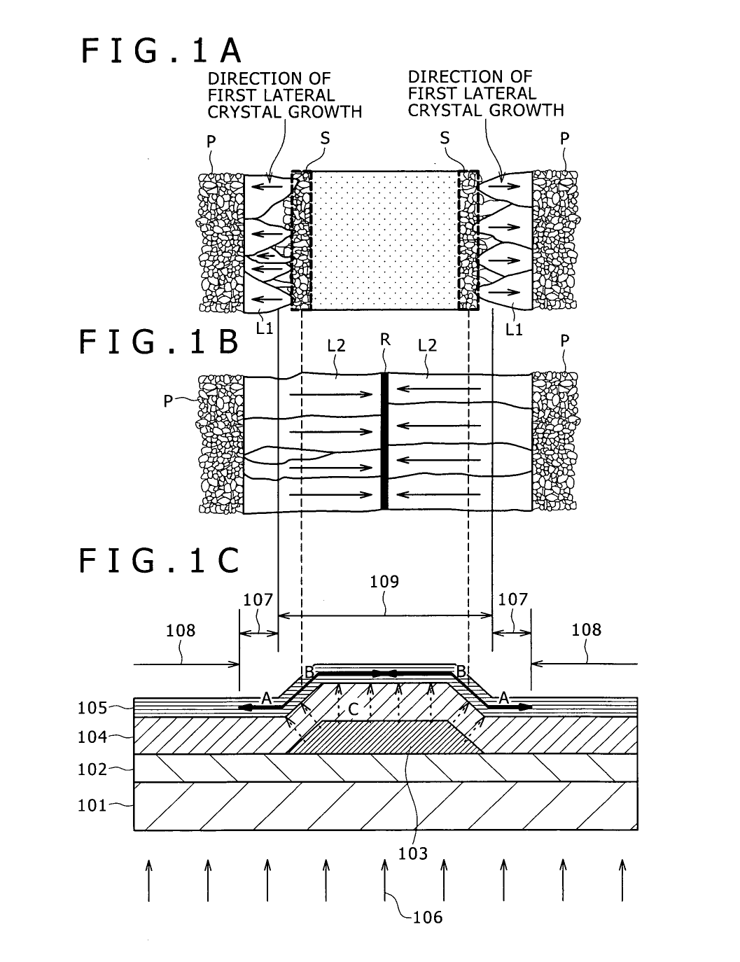

Now, embodiments of the present invention will be described in detail below, referring to the drawings. FIGS. 1A to 1C are schematic diagrams showing major points of the method of manufacturing a thin film semiconductor device according to the present invention, in which FIG. 1C are schematic sectional diagram of the semiconductor device, and FIGS. 1A and 1B are plan diagrams showing a phase change of a semiconductor thin film appearing in the manufacturing process. Basically, the method of manufacturing a thin film semiconductor device according to the present invention includes a light absorbing layer forming step, a patterning step, an insulation film forming step, a semiconductor thin film forming step, and a laser annealing step. As shown in FIG. 1C, in the light absorbing layer forming step, first, a light absorbing layer 103 is formed on the face side of a transparent substrate 101 formed of a glass or the like. In this embodiment, a thermal buffer layer 102 is preliminarily formed on the face side of the substrate 101, and the light absorbing layer 103 is formed thereon. Subsequently, in the patterning step, the light absorbing layer 103 is patterned into a predetermined shape by etching. Next, in the insulation film forming step, the patterned light absorbing layer 103 is covered with an insulation film 104. Further, in the semiconductor thin film forming step, a semiconductor thin film 105 is formed on the insulation film 104. The semiconductor thin film 105 is, for example, an amorphous silicon film. Finally, in the laser annealing step, irradiation with pulsedly oscillated laser light 106 from the back side of the substrate 101 is conducted to crystallize the semiconductor thin film 105.

The laser annealing step constituting a characteristic part of the present invention includes first to fourth processes. In the first process, irradiation with the laser light 106 is conducted, whereby an external region (107, 108) of the semiconductor thin film 105 located on the outer side relative to the pattern of the light absorbing layer 103 is thermally melted, and the light absorbing layer 103 is heated, without melting an internal region (109) of the semiconductor thin film 105 located on the inner side relative to the pattern of the light absorbing layer 103. In the subsequent second process, the molten semiconductor thin film 105 is cooled, and microcrystal grains S, P are formed in the external region (107, 108). In the second process, the semiconductor thin film once heated to or above the melting point thereof by the irradiation with the laser light is brought into a supercooled state, and random nucleation upon the supercooling provides seeds for crystallization, so that the crystal grains are fine in diameter.

In the third process shown in FIG. 1A, a first lateral crystal growth progresses from the boundary between the external region (107) and the internal region (109) toward the outer side with the microcrystal grains S as nuclei, and polycrystal grains L1 greater than the microcrystal grains S are produced in the area of the external region (107) adjacent to the boundary. As indicated by arrows A in FIG. 1C, the third process progresses in lateral directions of the semiconductor thin film 105, and is therefore the so-called lateral crystal growth. As shown in FIG. 1A, the first lateral crystal growth progresses from the boundary between the internal region and the external region toward the outer side. In FIG. 1C, the external region where the first lateral crystal growth has occurred is referred to particularly a first lateral growth region 107. The first lateral growth region 107 ranges over a distance of at least 2 μm from the boundary toward the outer side. Since the lateral crystal growth does not occur in the outer region beyond the first lateral growth region 107, the outer region remains containing the microcrystal grains P. In FIG. 1C, this external region (outer region) is referred to as an ordinary polycrystalline region 108.

In the fourth process shown in FIG. 1B, heat is transferred from the light absorbing layer 103 heated by the irradiation with the laser light to the semiconductor thin film 105 through the insulation film 104, whereby the internal region (109) is melted. The directions of the heat transfer are indicated by arrows C in FIG. 1C. Subsequently, a second lateral crystal growth progresses from the boundary defined by the pattern of the light absorbing layer 103 toward the inner side, with the crystal grains L1 as nuclei, so that further enlarged polycrystal grains L2 are produced in the internal region (109). In FIG. 1C, the directions in which the second lateral crystal growth progresses are indicated by arrows B; in addition, the internal region where the second lateral crystal growth has occurred is referred to as a second lateral growth region 109. As shown in FIG. 1B, the second lateral crystal growth progresses from both sides of the pattern of the light absorbing layer 103 toward the inner side, and, therefore, a major grain boundary R of the polycrystal grains L2 is generated just at the center of the second lateral growth region 109. As is apparent from FIG. 1B, the sizes and positions of the polycrystal grains L2 contained in the second lateral growth region 109 are controlled geometrically according to the pattern of the light absorbing layer 103. The second lateral growth region 109 thus controlled evenly is utilized for forming a channel region of each thin film transistor, whereby thin film transistors uniform in characteristics can be integratedly formed on the substrate.

Preferably, the laser annealing step includes irradiating the substrate 101 with green laser light 106 having a wavelength range of from 520 to 540 nm. In addition, the laser annealing step in some cases includes irradiating the substrate 101 with pulsedly oscillated laser light 106 while scanning in such a range that the irradiation regions overlap with each other. Besides, in the light absorbing layer forming step, the light absorbing layer 103 may be formed by use of a conductive material, and, in the patterning step, the conductive material may be patterned, to produce a wiring including a gate electrode of a thin film transistor, for example. Furthermore, in the light absorbing layer forming step, a high melting point metal or an alloy or silicide containing a high melting point metal as a constituent thereof may be used as the conductive material for forming the light absorbing layer 103.

Continuedly referring to FIGS. 1A to 1C, the principle of the grain boundary position control conducted using the laser annealing according to the present invention will be described in detail. The melting of the semiconductor thin film 105 and the crystallization process with grain boundary controlled, which are generated attendant on the irradiation with the laser light 106, progress as follows. First, with the pattern of the light absorbing layer 103 used as a light-shielding mask, the semiconductor thin film 105 formed of amorphous silicon is irradiated with pulses of the laser light 106, whereby the semiconductor thin film 105 in the external region (107, 108) other than the area on the upper side of the pattern of the light absorbing layer 103 is melted and solidified. In this instance, the internal region (109) of the semiconductor thin film 105 located on the upper side of the pattern of the light absorbing layer 103 is not heated; therefore, the temperature of the melt of silicon located in the vicinity of the outer periphery of the pattern of the light absorbing layer 103 is firstly lowered into a supercooled state, and then random nucleus generation occurs, resulting in the formation of microcrystal grins S having a grain diameter of 0.1 μm or less. With part of the microcrystal grains S as seeds, the first lateral crystal growth progresses toward the outside, in the directions indicated by arrows in FIG. 1A. The lateral crystal growth in this case progresses under latent heat, and ranges typically over a width of 1 to 5 μm. The first lateral crystal growth does not range into the external region beyond this width, and the external region remains as the ordinary polycrystalline region 108 where the microcrystal grains P have been produced.

On the other hand, the pattern of the light absorbing layer 103 formed of a metal or the like is also directly heated by the irradiation with the laser light 106, and the heat is transferred to the thermal buffer layer 102 therebeneath and the insulation film 104 on the upper side. The heat transferred to the insulation film 104 is transferred to the internal region (109) composed of an unmelted amorphous silicon thin film, with a time delay of typically within 10 μs, to melt the amorphous silicon. It should be noted here that, by the time when the melting of the amorphous silicon begins, the first lateral crystal growth has already begun, or, depending on the conditions, has been completed and the polycrystal grains L1 have been formed. Therefore, the amorphous silicon in the internal region (109) is melted in the state of containing a part of the crystal grains L1 formed in the first lateral growth region 107, so that when temperature is lowered due to the subsequent dissipation of heat, the second lateral crystal growth with the unmelted crystal grains L1 as nuclei starts progressing from the outer peripheral portion of the pattern of the light absorbing layer 103 toward the inner side, and the polycrystal grains L2 are grown. The polycrystal grains L2 collide on each other at the center of the second lateral growth region, to form the major grain boundary R. Incidentally, in the case where the width of the pattern of the light absorbing layer 103 is shorter than two times the distance where lateral crystal growth is possible (typically, 1 to 10 μm), the major grain boundary R is not formed, and random nucleation attendant on the lowering in the temperature of the silicon melt occurs in the vicinity of the center in the width direction of the second lateral growth region 109, before the fronts of lateral crystal growth progressing from both sides of the pattern toward the inner side collide on each other. In this case, a microcrystalline region with a crystal grain diameter of 0.1 μm or less is formed along the center of the internal region (109), but there arises no special problem in using only the second lateral growth region 109 for forming a channel region.

FIG. 2 shows an optical microphotograph of a semiconductor thin film crystallized according to the present invention. The sample was obtained by forming a gate electrode on the upper side of a glass substrate, with a thermal buffer layer therebetween, and forming an amorphous silicon film on the upper side of the gate electrode, with a gate insulation film therebetween. The sample was irradiated once with green laser from the back side, to convert amorphous silicon into polycrystalline silicon. The gate electrode was formed of a high melting point metal, and played the role of a light absorbing layer. The pattern of the gate electrode had a width of about 6 μm. As is apparent from the figure, polycrystal grains produced by the second lateral crystal growth are orderly arrayed in the internal region overlapping with the gate electrode. The polycrystal grains grown from both sides of the gate electrode pattern toward the inner side had collide on each other at the center in the width direction of the pattern, to form a major grain boundary. In addition, polycrystal grains produced by the first lateral crystal growth are orderly arrayed, from the outer periphery of the gate electrode pattern toward the outer side. The first lateral crystal region is formed in a width of about 2 μm from the outer periphery of the electrode pattern. In the outer region on the further outer side of the first lateral crystal region, microcrystal grains have been formed. The microcrystal grains are too fine in grain diameter to be observed under an optical microscope.

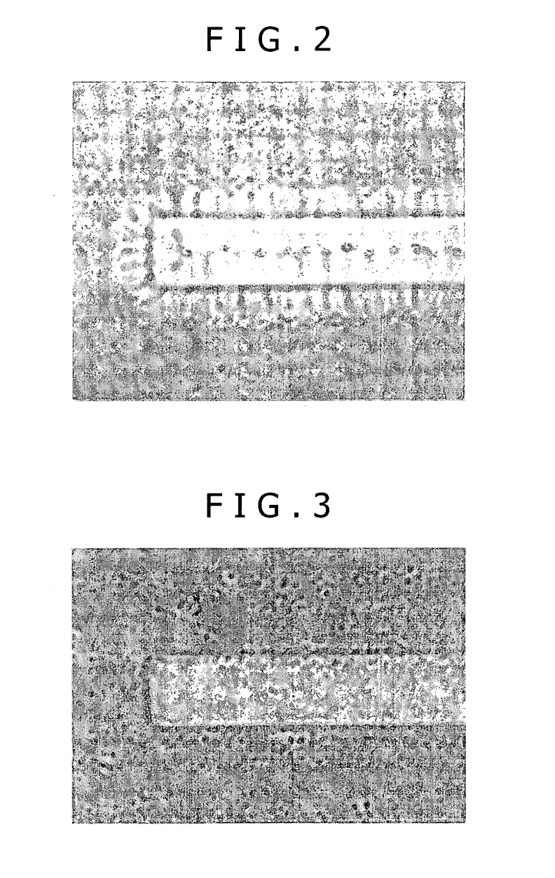

FIG. 3 is an optical microphotograph showing the state, after one run of irradiation with green laser from the face side of the glass substrate, of the same sample as shown in FIG. 2. As is apparent from the figure, lateral crystal growth did not occurred, and only microcrystal grains were formed in both the internal region and the external region of the gate electrode pattern.

As is clear from the foregoing, according to the present invention, the melting of the external region of the semiconductor thin film located on the outside of a gate electrode pattern and the melting of the internal region of the semiconductor thin film located on the inside of the gate electrode pattern can be sequentially performed with a delay time of within 10 μs, by one run of irradiation with laser light. Thus, the generation of a time delay during the process in which the metallic gate electrode is heated by irradiation with laser light and then the heat is transferred to the silicon film with the result of melting of silicon is tactfully utilized. Therefore, the treatment needs only one simple run of uniform irradiation, so that the irradiation apparatus can be simplified, and the throughput is enhanced remarkably.

Incidentally, the melting of the internal region located on the inside of the gate electrode requires a higher laser light energy density (area density), as compared with the melting of silicon in the external region located on the outside of the gate electrode. This is because the metallic gate electrode has a great heat capacity, so that a greater amount of heat is needed accordingly, and because the transfer of heat to the silicon layer is accompanied by dissipation of heat into the glass substrate. Taking this into consideration, green laser light is used in the present invention. The green laser light shows less absorption into a silicon layer, as compared with UV excimer laser light. For example, at room temperature, green laser light incident on a silicon layer is absorbed into the silicon layer in a proportion of only 5 to 10%. With the green laser light thus utilized, the metallic gate electrode can be heated in a high energy density, while the external region on the outside of the gate electrode pattern can be heated in a low energy density. As a result, the first lateral crystal growth and the second lateral crystal growth can be induced sequentially. In consideration of the use of the semiconductor thin film as a thin film transistor, the internal region on the inside of the gate electrode pattern has a high crystal uniformity, so that the internal region can be used for forming a channel region. In addition, polycrystal grains are orderly arrayed in a width of about 2 μm along the outer periphery of the gate electrode pattern. This portion can be used for forming an LDD region of a thin film transistor, which is very convenient on a device design basis.

According to the method of the present invention, the size of polycrystalline silicon grains and the position of the polycrystalline silicon grain boundary can both be controlled according to the metallic wiring pattern such as the gate electrode formed prior to the crystal growth, and, when the region of the polycrystalline silicon grains is used for forming a channel region of a thin film transistor, the characteristics of the transistor and the uniformity thereof are conspicuously enhanced. In addition, it suffices to conduct only one run of irradiation with laser light, which promises an enhancement of treatment rate by a factor of about 10 to 20 times, as compared with the repeated irradiation treatment according to the prior art in which the irradiation is carried out about 10 to 20 times per one location. Furthermore, the crystallinity and thin film transistor characteristics are little changed even where the irradiation is carried out two times instead of once, so that the irradiation treatment can be conducted while scanning in such a manner that the laser light irradiation regions partly overlap with each other. In this case, a semiconductor thin film larger in area than the irradiation region can be crystallized uniformly.

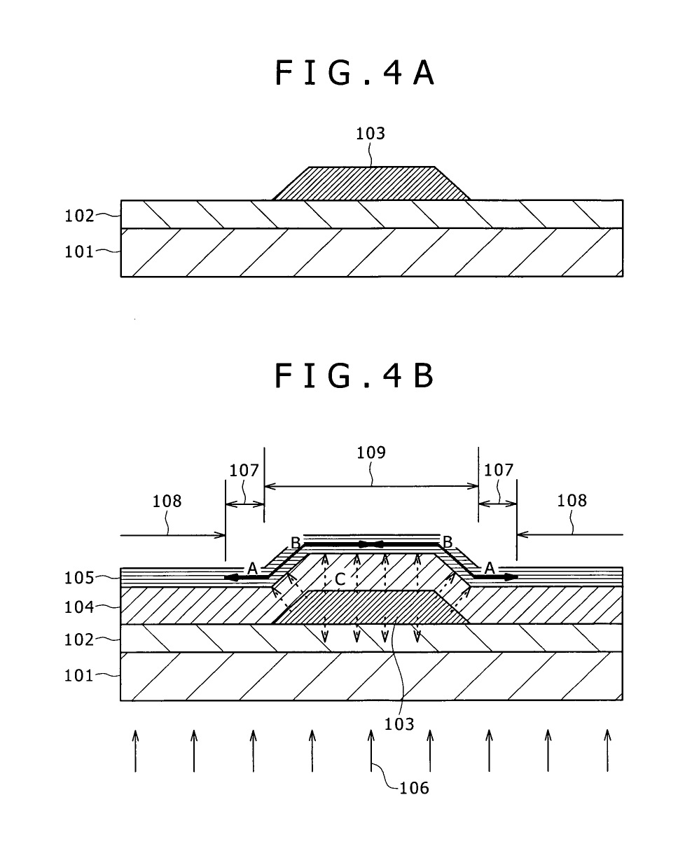

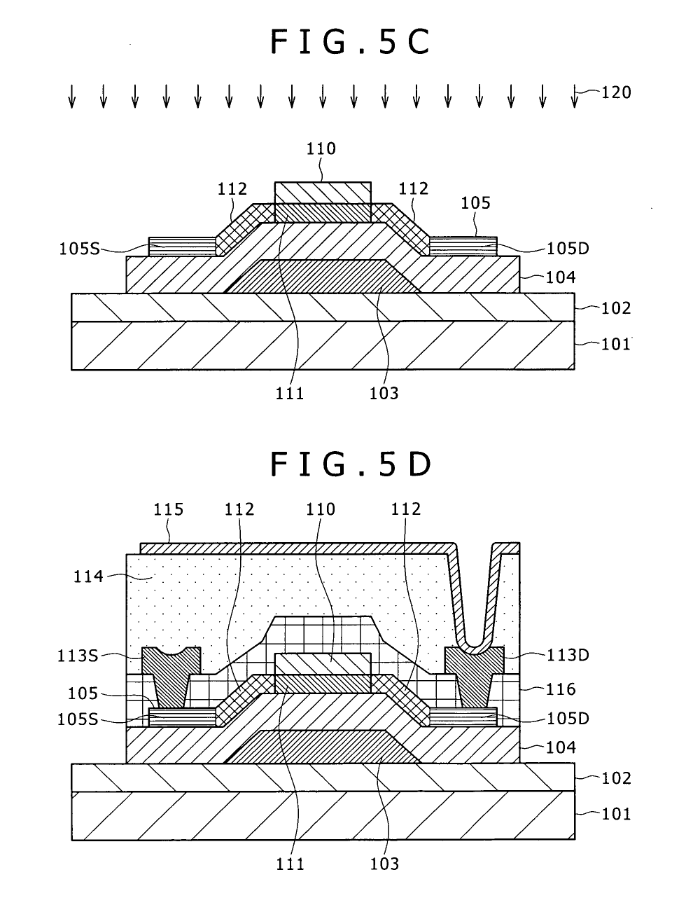

Referring now to FIGS. 4A to 5D, a first embodiment of the method of manufacturing a thin film semiconductor device according to the present invention will be described in detail. In the first embodiment, a thin film transistor of the bottom gate structure is formed on an insulating substrate formed of a glass or the like. First, as shown in FIG. 4A, a thermal buffer layer 102 composed of two-layer structure of SiNₓ and SiO₂ is formed on the glass substrate 101, and then a metallic wiring pattern 103 including a gate electrode is formed thereon. In this embodiment, a 100 nm thick layer of SiNₓ and a 200 nm thick layer of SiO₂ were formed by plasma CVD, to constitute the thermal buffer layer 102. Thereafter, a 100 nm thick thin film of molybdenum was formed by magnetron sputtering, and the metallic wiring pattern 103 with a width in the range of 2 to 20 nm was formed by photolithography and reactive ion etching.

Next, as shown in FIG. 4B, a 50 nm thick layer of SiNₓ and a 100 nm thick layer SiO₂ were formed by plasma CVD to constitute a gate insulation film 104, and subsequently, by only changing over the raw material gases, an about 30 to 100 nm thick semiconductor thin film 105 of amorphous silicon was formed by plasma CVD. Thereafter, in a nitrogen atmosphere, a so-called dehydrogeneration annealing treatment was conducted by heat-treating in a furnace at a temperature of 400° C. for about 1 to 3 hr, to reduce the amount of hydrogen in the amorphous silicon thin film 105 to 0.1 to 2 at. %. Incidentally, the dehydrogeneration annealing treatment is not needed, if the amorphous silicon thin film 105 is formed by a method promising essentially a low hydrogen content, such as sputtering, LP-CVD, etc. Furthermore, the annealing in the furnace may be replaced by the so-called laser dehydrogenating treatment in which the silicon thin film is heated by irradiation with laser light in a comparatively low energy density such that the silicon thin film is not completely melted.

Next, the glass substrate 101 is irradiated once with a second harmonic output type laser light 106 pulsedly oscillated from a solid state laser, from the back side through an appropriate irradiation optical system. As the solid state laser, there may be used the second harmonic outputs of pulse oscillation Q switch Nd:YAG laser and Nd:YLF laser. The wavelengths of these harmonic outputs are 532 nm and 527 nm, respectively. The laser diode excitation and flash lamp excitation may be similarly adopted; from the viewpoints of output stability and excitation light source replacement cycle, however, the laser diode excitation is preferred. Examples of the solid state laser which can be used include the Evolution Series (oscillation wavelength: 527 nm) and the CORONA Series (oscillation wavelength: 532 nm), both produced by Coherent, USA. In this embodiment, Evolution 30 by Coherent, USA, was used in the oscillation conditions of a repetition frequency of 1 kHz, a pulse width of about 150 nm, and a pulse energy of 20 mJ. As for the irradiation system, a line form beam processed by a uniformizing optical system composed of a condenser lens, a fly eye lens and the like to uniformize the light intensity distribution in an irradiation spot to within ±5% and then shaped by a shaping optical system composed of a cylindrical lens, a slit and a condenser lens into a shape having a length of 2 mm and a width of 0.3 mm, was used. The energy density was set to within the range of 1 to 2 J/cm². By scanning with the line form beam in the width direction, a semiconductor thin film having a large area can be crystallized.

By the irradiation with the laser beam, the portion, directly above the gate electrode pattern 103, of the semiconductor thin film 105 is converted into a second lateral growth region 109. On the other hand, the portion, surrounding the outer periphery of the gate electrode pattern 103, of the semiconductor thin film 105 becomes a first lateral growth region 107. The outside portion, beyond the first lateral growth region 107, of the semiconductor thin film 105 becomes an ordinary polycrystalline region 108 composed of microcrystal grains. As has been described above, the growth directions of the first lateral growth region 107 are indicated by arrows A. On the other hand, the growth directions of the second lateral growth region 109 are indicated by arrows B. The directions of transfer of heat for inducing the second lateral crystal growth are indicated by arrows C.

Subsequently, as shown in FIG. 5C, for the purpose of controlling the threshold voltage Vth of the thin film transistor, the polycrystallized semiconductor thin film 105 is subjected to Vth ion implantation, as required. Here, for example, B⁺ ions are implanted at an acceleration energy of 10 keV and a dose of about 5×10¹¹ to 4×10¹²/cm².

Next, an insulating stopper film 110 is formed on the semiconductor thin film 105, which has been crystallized in the preceding step, in the state of being matched to the gate electrode 103. In this case, an SiO₂ film is first formed in a thickness of about 100 to 300 nm by plasma CVD. Here, for example, silane gas SiH4 and nitrous oxide N₂O are subjected to plasma dissociation, thereby building up the SiO₂ film. Then, the SiO₂ film is patterned into a predetermined shape, to obtain the stopper film 110. In this case, the stopper film 110 is patterned in such a manner as to achieve self-alignment with the gate electrode 103, by use of a back exposure technique. Incidentally, the portion, located beneath the stopper film 110, of the semiconductor thin film 105 is protected as a channel region 111. As has been described above, B⁺ ions have preliminarily been implanted into the channel region 111 in a comparatively low dose by the Vth ion implantation.

Subsequently, with the stopper film 110 as a mask, an impurity (P⁺ ion) is implanted into the semiconductor thin film 105 by ion doping 120, to form LDD regions 112. In this case, for example, the dose is 5×10¹² to 1×10¹³/cm², and the acceleration voltage is 10 keV. Further, a photoresist (omitted in the figure) is formed and patterned so as to cover the stopper film 110 and the LDD regions 112 on both sides thereof, then, with the photoresist pattern as a mask, an impurity 120 (e.g., P⁺ ion) is implanted into the semiconductor thin film 105 in a high concentration, to form a source region 105S and a drain region 105D. For example, ion doping 120 (ion shower) can be used for the impurity implantation. This technique resides in implanting the impurity by electric field acceleration, without applying mass separation; for example, the impurity is implanted in a dose of about 1×10¹⁵/cm², to form the source region 105S and the drain region 105D. The acceleration voltage is 10 keV, for example.

Following to the foregoing, the impurities implanted into the semiconductor thin film 105 are activated by RTA (Rapid Thermal Anneal) using a UV lamp. Thereafter, unrequired portions of he semiconductor thin film 105 and the gate insulation film 104 are removed by patterning, to form bottom gate type thin film transistors and to separate the thin film transistors on a device basis.

Thereafter, as shown in FIG. 5D, an about 100 to 200 nm thick layer of SiO₂ and an about 200 to 400 nm thick layer of SiNₓ are successively formed in such a manner as to cover the thin film transistor on the substrate 101 by plasma CVD, to constitute a layer insulation film 116. In this stage, a so-called hydrogenation annealing was conducted in which a heat treatment at about 350 to 400° C. in a nitrogen gas or foaming gas atmosphere or in vacuum is conducted for 1 hr so as to diffuse the hydrogen atoms contained in the layer insulation film 116 into the semiconductor thin film 105. Thereafter, contact holes are opened in the layer insulation film, a layer of Mo, Al or the like is formed in a thickness of 100 nm to 1 μm by sputtering, and thereafter the sputtered layer is patterned into a predetermined shape, to form a source electrode 113S and a drain electrode 113D connected to the source region 105S and the drain region 105D, respectively. Furthermore, a flattening layer 114 composed of a photosensitive acrylic resin or the like is formed in a thickness of about 1 to 3 μm by coating, followed by photolithography to open a contact hole reaching the drain electrode 113D. Then, a transparent conductive film composed of indium tin oxide (In₂O₃+SnO₂, hereinafter referred to as ITO) or a reflective conductive film composed of Ag, Al or the like is formed on the flattening layer 114 by sputtering, and is patterned into a predetermined shape, to form a pixel electrode 115 connected to the drain electrode 113D.

In the above-mentioned manner, a thin film semiconductor device having the thin film transistor provided on the insulating substrate 101 is completed. As has been described above, the thin film transistor includes the semiconductor thin film 105 and the gate electrode 103 laminated, with the gate insulation film 104 therebetween. The semiconductor thin film 105 has the channel region 111 overlapping with the gate electrode 103, and the source region 105S and the drain region 105D which are located respectively on both sides of the channel region 111. The semiconductor thin film 105 is a polycrystalline layer crystallized by laser annealing, and is divided along the boundary of a predetermined pattern into the internal region and the external region (FIG. 4B). The external region has the first lateral growth region 107 which contains the polycrystal grains laterally grown from the pattern boundary toward the outer side by the laser annealing. The internal region has the second lateral growth region 109 which contains the polycrystal grains laterally grown from the pattern boundary toward the inner side, with the polycrystal grains contained in the first lateral growth region 107 as nuclei. Here, the channel region 111 (FIG. 5D) of the thin film transistor is formed in the second lateral growth region 109 (FIG. 4B).

The semiconductor thin film 105 is a polycrystalline layer polycrystallized by the laser annealing conducted by irradiation with the laser light 106 through the light absorbing layer formed in the predetermined pattern. As shown in FIG. 4B, the light absorbing layer is used later as the gate electrode 103. Preferably, the source region 105S and the drain region 105D are formed in the first lateral growth region 107. In addition, the thin film transistor includes the LDD region 112, which is lower in impurity concentration than the drain region 115D, between the channel region 111 and at least the drain region 105D. The LDD region 112 is formed in the first lateral growth region 107 or the second lateral growth region 109.

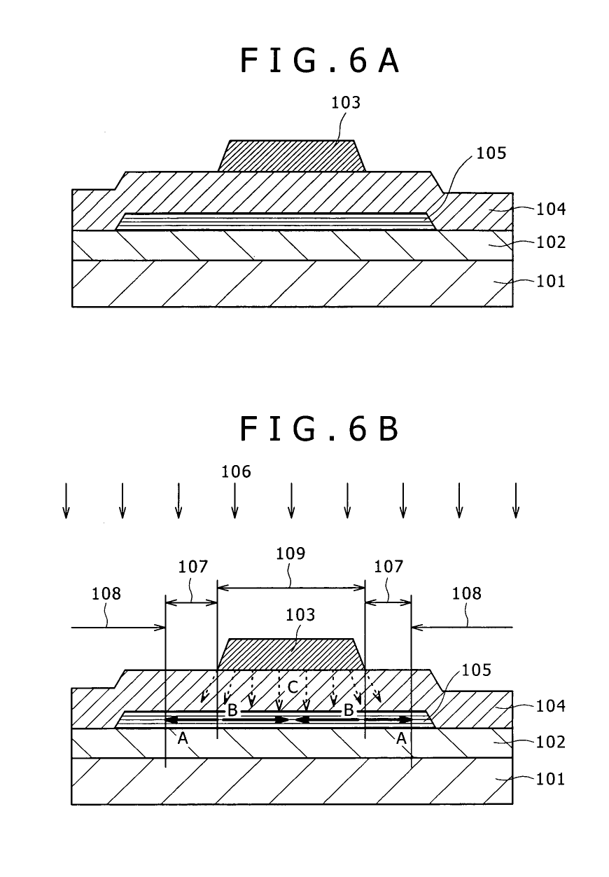

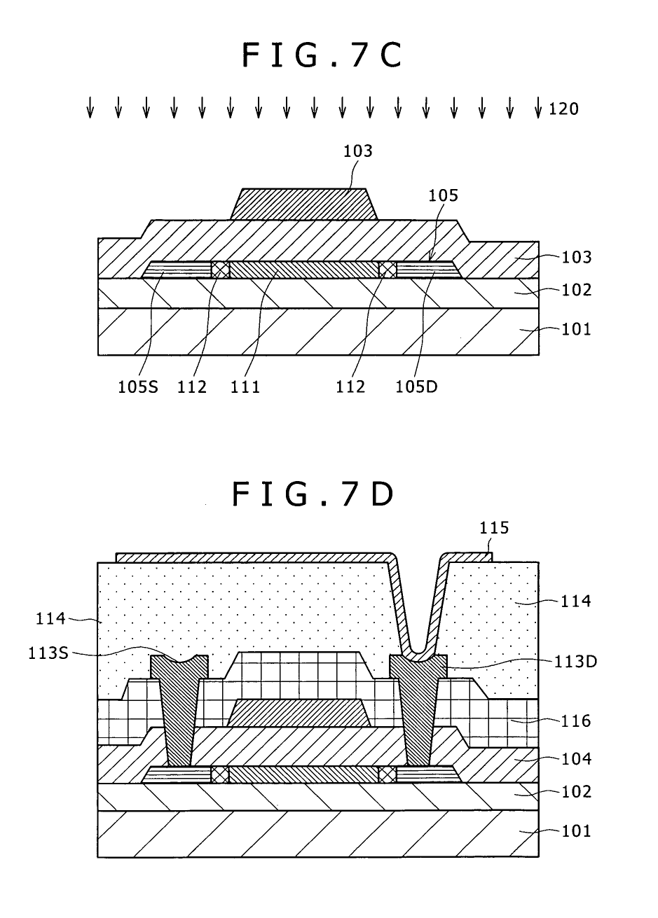

Now, referring to FIGS. 6A to 7D, a second embodiment of the method of manufacturing a thin film semiconductor device according to the present invention will be described below. In this embodiment, a top gate type thin film transistor is formed on an insulating substrate. First, as shown in FIG. 6A, under-layer films of a two-layer structure to be a thermal buffer layer (buffer layer) 102 are successively formed on the insulating substrate 101 by plasma CVD. The under-layer film constituting the first layer is composed of SiNₓ, and has a thickness of 100 to 200 nm. The under-layer film constituting the second layer is composed of SiO₂, and similarly has a thickness of 100 to 200 nm. A semiconductor thin film 105 composed of amorphous silicon is formed in a thickness of about 30 to 80 nm on the thermal buffer layer 102 by plasma CVD or LP-CVD. In the case where the LP-CVD is used for forming the amorphous silicon semiconductor thin film 105, an annealing in a nitrogen atmosphere at 400 to 450° C. for about one hr is conducted, for reducing the amount of hydrogen contained in the film. Here, if required, Vth ion implantation is conducted, as has been described above, to implant B⁺ into the amorphous silicon semiconductor thin film 105 in a dose of, for example, about 5×10¹¹ to 4×10¹²/cm². The acceleration voltage in this case is about 10 keV.

Subsequently, the semiconductor thin film 105 is patterned into an island-like shape. On the semiconductor thin film 105 thus patterned, SiO₂ is grown to a thickness of 10 to 400 nm (here, for example, 100 nm) by plasma CVD, normal pressure CVD, reduced pressure CVD, ECR-CVD, sputtering or the like, to form a gate insulation film 104.

Next, a film of a high melting point metal such as Ti, Mo, W, Ta, etc. or an alloy thereof is formed in a thickness of 100 to 800 nm on the gate insulation film 104, and is patterned into a predetermined shape, to form a gate electrode 103. The portion, located beneath the gate electrode 103, of the semiconductor thin film 105 is a portion which will later be a channel region. As has been described above, B⁺ ions have been preliminarily implanted into this portion in a comparatively low dose by the Vth ion implantation.

Subsequently, as shown in FIG. 6B, irradiation with pulsedly oscillated laser light 106 from the upper side of the substrate 101 is conducted, to crystallize the semiconductor thin film 105. This laser annealing is carried out through first to fourth processes. First, in the first process, an external region (107, 108) of the semiconductor thin film 105 located on the outer side relative to the pattern of the gate electrode 103 is thermally melted, and the gate electrode 103 is heated, without melting an internal region (109) of the semiconductor thin film 105 located on the inner side relative to the pattern of the gate electrode 103. Subsequently, in the second process, the molten semiconductor thin film 105 is cooled, whereby microcrystal grains are produced in the vicinity of the boundary between the external region (107) and the internal region (109). Subsequently, the third process takes place, in which a first lateral crystal growth progresses from the boundary between the external region and the internal region toward the outer side as indicated by arrows A, with the microcrystal grains as nuclei, to form a first lateral growth region 107 wherein polycrystal grains larger than the microcrystal grains are produced in the area of the external region adjacent to the boundary. The external region of the first lateral growth region 107 is an ordinary polycrystalline region 108 composed of the microcrystal grains. Further, with a predetermined delay of time from the third process, the fourth process takes place. In the fourth process, heat is transferred from the heated gate electrode 103 to the semiconductor thin film 105 through the gate insulation film 104 as indicated by arrows C, whereby the internal region is melted, and thereafter a second lateral crystal growth progresses from the boundary toward the inner side as indicated by arrows B, with the polycrystal grains as nuclei, whereby further enlarged polycrystal grains are produced in the internal region, to form a second lateral growth region 109.

Subsequently, as shown in FIG. 7C, P⁺ ions 120 are implanted into the crystallized semiconductor thin film 105 by ion implantation using mass separation, to provide LDD regions 112. The ion implantation is applied to the whole surface of the polycrystalline silicon semiconductor thin film 105, using the gate electrode 103 as a mask. The dose is 6×10¹² to 5×10¹³/cm², and the acceleration voltage is, for example, 90 keV. Thereafter, a resist pattern (omitted in the figure) is formed so as to cover the gate electrode 103 and the surroundings thereof, and P⁺ ions 120 are implanted in a high concentration by ion implantation, to form a source region 105S and a drain region 105D. In this case, the dose is, for example, about 1×10¹⁵/cm², the acceleration voltage is, for example, 90 keV, and PH₃ gas is used as the doping gas.

Thereafter, the dopant implanted into the polycrystalline silicon semiconductor thin film 105 is activated. The activating treatment can be conducted by RTA (Rapid Thermal Anneal) using a UV lamp, in the same manner as in manufacturing the bottom gate type thin film transistor.

Thereafter, as shown in FIG. 7D, an about 100 to 200 nm thick layer of SiO₂ and an about 200 to 400 nm thick layer of SiNₓ were successively formed by plasma CVD so as to cover the thin film transistor on the insulating substrate 101, to form a layer insulation film 116. In this stage, a so-called dehydrogenation annealing was conducted in which a heat treatment in a nitrogen gas or foaming gas atmosphere or in vacuum at about 350 to 400° C. was conducted for one hr, to diffuse the hydrogen atoms contained in the layer insulation film 116 into the polycrystalline silicon semiconductor thin film 105. Thereafter, contact holes are opened in the layer insulation film 116 and the gate insulation film 104, then a film of Al—Si or the like is formed by sputtering, and the sputtered film is patterned into a predetermined shape, to form a source electrode 113S and a drain electrode 113D. Furthermore, a flattening layer 114 composed of a photosensitive acrylic resin or the like is formed in a thickness of about 1 to 3 μm, followed by photolithography to open a contact hole reaching the drain electrode 113D. A transparent conductive film composed of ITO or the like or a reflective electrode film composed of Ag, Al or the like is formed on the flattening layer 114 by sputtering, and is then patterned into a predetermined shape, to form a pixel electrode 115 connected to the drain electrode 113D.

As a result, a top gate type thin film transistor is completed. The thin film transistor has the channel region 111 formed in the second lateral growth region 109. On the other hand, the source region 105S and the drain region 105D are formed in the first lateral growth region 107. In addition, the LDD regions 112 are formed in the first lateral growth region 107 or the second lateral growth region 109. Incidentally, in the case of the top gate type thin film transistor, the upper side of the semiconductor thin film is closed with the metallic gate electrode, so that the release path for the hydrogen gas generated attendant on the melting of silicon is smaller, as compared with the case of the bottom gate type thin film transistor. Therefore, it is important for the dehydrogenating treatment of the semiconductor thin film to be preliminarily carried out with special care.

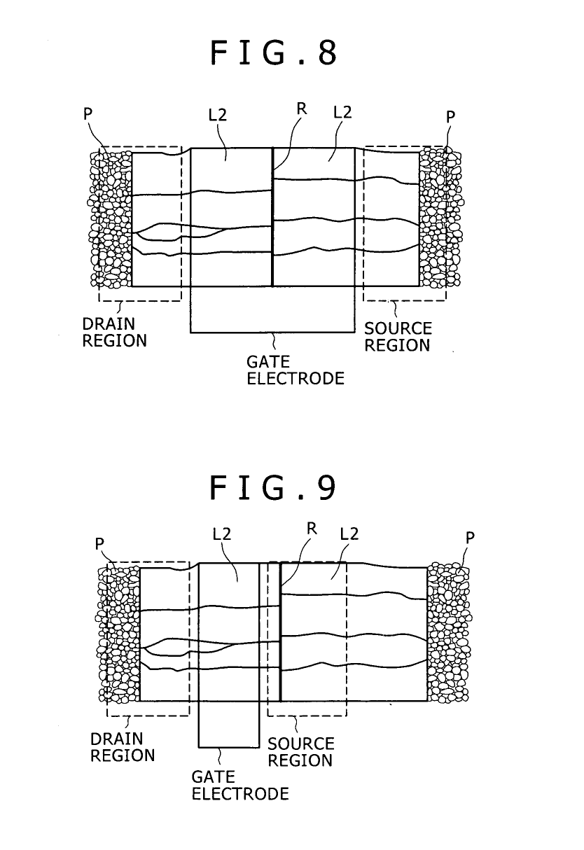

FIG. 8 is a schematic plan diagram showing the crystal structure of a device region of a thin film transistor formed according to the present invention. As shown in the figure, where laser annealing of the present invention is carried out, a second lateral growth region is formed beneath the gate electrode, and this region forms a channel region. The second lateral growth region is composed of polycrystal grains L2 having grain boundaries orderly arrayed. While the ordinary grain boundaries separating the individual polycrystal grains are parallel to the longitudinal direction of the channel region, the major grain boundary R at the center of the channel region is parallel to the width direction of the channel region. In the case of the bottom gate structure, the major grain boundary R appears as a protuberant portion on the face side of the polycrystalline silicon semiconductor thin film. In addition, the region ranging from an end portion of the gate electrode toward the outer side over a distance of typically 2 μm or less is also a region of laterally grown crystals. In the present invention, the first lateral growth region is also utilized as a source region and a drain region or as LDD regions. The silicon thin film in the external region remote from the gate electrode end portion by typically 2 μm or more is in a microcrystalline state with an ordinary grain diameter of 0.1 μm or less, formed upon one run of irradiation with laser light. This microcrystal region is not used for forming the channel region of the thin film transistor and, therefore, produces no special problem.

FIG. 9 is a plan diagram showing a structure in which not all but only a part of the second lateral growth region is utilized for forming a channel region, which structure is useful particularly for a top gate type thin film transistor. In the case of the top gate type, the gate electrode is formed while avoiding the major grain boundary R as shown in the figure, whereby electric characteristics of the thin film transistor can be made uniform. In this case, incidentally, the light absorbing layer used as a mask at the time of laser annealing is further patterned, to obtain the gate electrode. The portion, staggered from the pattern of the gate electrode, of the second lateral growth region can be utilized, for example, as the source region.

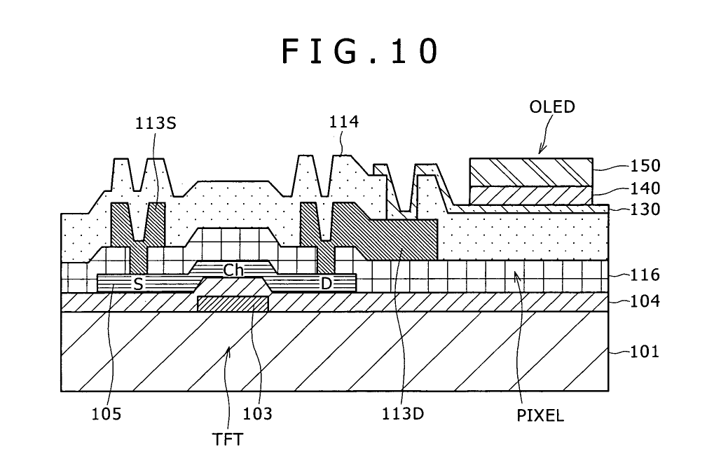

Finally, FIG. 10 is a schematic sectional diagram showing one example of the display according to the present invention. For easy presentation of the drawing, only one pixel and one thin film transistor TFT for driving the pixel are shown in the figure. The pixels are arranged in a matrix pattern, to constitute a screen. In this embodiment, the pixel is composed of an organic EL light emitting device OLED, including a transparent electrode 130, an organic EL layer 140 and a metallic electrode 150 laminated sequentially on one another. The transparent electrodes 130 are separated on a pixel basis, function as anodes A of the OLEDs, and are composed of a transparent conductive film, for example, ITO film. The metallic electrode 150 is connected in common for pixels, and functions as cathodes K of the OLEDs. The organic EL layer 140 is a composite film obtained by laminating a hole transport layer and an electron transport layer, for example. For example, Diamyle is vapor deposited as the hole transport layer on the transparent electrode 130 functioning as the anode A (hole injection electrode), Alq3 is vapor deposited thereon as the electron transport layer, and the metallic electrode 150 functioning as the cathode K (electron injection electrode) is produced thereon. Incidentally, “Alq3” represents 8-hydroxyquinoline aluminum. The OLED having such a laminate structure is merely an example. When a forward voltage is impressed between the anode and the cathode of the OLED having such a structure, injection of carriers such as electrons and holes occurs, and luminescence (emission of light) is observed. The operation of the OLED is considered to be luminescence (emission of light) by excitons formed from the holes injected from the hole transport layer and the electrons injected from the electron transport layer.

On the other hand, the TFT is produced according to the present invention, and is composed of a gate electrode 103 formed on a substrate 101 composed of a glass or the like, a gate insulation film 104 laminated thereon, and a semiconductor thin film 105 formed on the upper side of the gate electrode 103, with the gate insulation film 104 therebetween. The semiconductor thin film 105 is composed of a thin film of polycrystalline silicon laterally grown according to the present invention. The thin film transistor TFT includes a source S, a channel Ch and a drain D, which constitute a path for a current supplied to the OLED. The channel Ch is located just above the gate electrode 103. The TFT in this bottom gate structure is covered with a layer insulation film 116, on which are formed a source electrode 113S and a drain electrode 113D. On these electrodes is formed the above-mentioned OLED, with another layer insulation film 114 therebetween. A contact hole is opened in the layer insulation film 114, and the transparent electrode 130 of the OLED is electrically connected to the drain electrode 113D of the TFT through the contact hole. Incidentally, while each pixel is composed of the organic electroluminescence device OLED in this embodiment, this is not limitative. For example, the pixel can be composed of a pixel electrode connected to a thin film transistor TFT, a counter electrode opposed thereto, and a liquid crystal held between the electrodes.

It should be understood by those skilled in the art that various modifications, combinations, sub-combinations and alterations may occur depending on design requirements and other factors insofar as they are within the scope of the appended claims or the equivalents thereof.

What is claimed is:

1. A method of manufacturing a thin film semiconductor device, comprising a light absorbing layer forming step for forming a light absorbing layer on the face side of a transparent substrate, a patterning step for patterning said light absorbing layer into a predetermined shape, an insulation film forming step for covering said patterned light absorbing layer with an insulation film, a semiconductor thin film forming step for forming a semiconductor thin film on said insulation film, and a laser annealing step for irradiating said substrate with laser light pulsedly oscillated from the back side of said substrate so as to crystallize said semiconductor thin film, wherein
said laser annealing step comprises:
a first process in which an external region of said semiconductor thin film located on the outer side relative to the pattern of said light absorbing layer is thermally melted, and said light absorbing layer is heated, without melting an internal region of said semiconductor thin film located on the inner side relative to the pattern of said light absorbing layer;
a second process in which said molten semiconductor thin film is cooled and microcrystal grains are produced in the vicinity of the boundary between said external region and said internal region;
a third process in which a first lateral growth progresses from said boundary between said external region and said internal region toward the outer side with said microcrystal grains as nuclei so that polycrystal grains greater than said microcrystal grains are produced in the area of said external region adjacent to said boundary; and
a fourth process in which heat is transferred from said heated light absorbing layer to said semiconductor thin film through said insulation film, whereby said internal region is melted, and thereafter a second lateral growth progresses from said boundary toward the inner side with said polycrystal grains as nuclei so that further enlarged polycrystal grains are produced in said internal region.

2. A method of manufacturing a thin film semiconductor device, comprising a semiconductor thin film forming step for forming a semiconductor thin film on a substrate, an insulation film forming step for forming an insulation film thereon, a light absorbing layer forming step for forming a light absorbing layer on the upper side of said semiconductor thin film, with said insulation film therebetween, a patterning step for pattering said light absorbing layer into a predetermined shape, and a laser annealing step for irradiating said substrate with laser light pulsedly oscillated from the upper side of said substrate so as to crystallize said semiconductor thin film, wherein
said laser annealing step comprises:
a first process in which an external region of said semiconductor thin film located on the outer side relative to the pattern of said light absorbing layer is thermally melted, and said light absorbing layer is heated, without melting an internal region of said semiconductor thin film located on the inner side relative to the pattern of said light absorbing layer;
a second process in which said molten semiconductor thin film is cooled and microcrystal grains are produced in the vicinity of the boundary between said external region and said internal region;
a third process in which a first lateral growth progresses from said boundary between said external region and said internal region toward the outer side with said microcrystal grains as nuclei so that polycrystal grains greater than said microcrystal grains are produced in the area of said external region adjacent to said boundary; and
a fourth process in which heat is transferred from said heated light absorbing layer to said semiconductor thin film through said insulation film, whereby said internal region is melted, and thereafter a second lateral growth progresses from said boundary toward the inner side with said polycrystal grains as nuclei so that further enlarged polycrystal grains are produced in said internal region.

3. The method of manufacturing a thin film semiconductor device as set forth in claim 1 or 2, wherein said laser annealing step comprises irradiating said substrate with laser light having a wavelength range of from 520 to 540 nm.

4. The method of manufacturing a thin film semiconductor device as set forth in claim 1 or 2, wherein said laser annealing step comprises irradiating said substrate with said pulsedly oscillated laser light while scanning in such a range that irradiated regions overlap with each other.

5. The method of manufacturing a thin film semiconductor device as set forth in claim 1 or 2, wherein said light absorbing layer forming step comprises forming said light absorbing layer by use of a conductive material, and said patterning step comprises patterning said conductive material so as to produce a wiring including a gate electrode.

6. The method of manufacturing a thin film semiconductor device as set forth in claim 5, wherein said light absorbing layer forming step is carried out by using a high melting point metal or an alloy or silicide containing a high melting point metal as a constituent thereof, as said conductive material for forming said light absorbing layer.

7. A thin film semiconductor device comprising an insulating substrate provided integratedly with thin film transistors, wherein
each said thin film transistor comprises a semiconductor thin film and a gate electrode laminated, with a gate insulation film therebetween;
said semiconductor thin film comprises a channel region overlapping with said gate electrode, and a source region and a drain region which are located respectively on both sides of said channel region;
said semiconductor thin film is a polycrystalline layer crystallized by laser annealing, and is divided along the boundary of a predetermined pattern into an internal region and an external region;
said external region has a first lateral growth region containing polycrystal grains laterally grown from said boundary toward the outer side by said laser annealing;
said internal region has a second lateral growth region containing polycrystal grains laterally grown from said boundary toward the inner side with said polycrystalline contained in said first lateral growth region as nuclei; and
said channel region is formed in said second lateral growth region.

8. The thin film semiconductor device as set forth in claim 7, wherein said semiconductor thin film is a polycrystalline layer crystallized by said laser annealing conducted by irradiation with laser light through a light absorbing layer formed in a predetermined pattern, and is formed through: a first process in which said external region located on the outer side relative to the pattern of said light absorbing layer is thermally melted, and said light absorbing layer is heated, without melting said internal region located on the inner side relative to the pattern of said light absorbing layer; a second process in which said molten semiconductor thin film is cooled and microcrystal grains are produced in the vicinity of said boundary between said external region and said internal region; a third process in which a first lateral growth progresses from said boundary between said external region and said internal region toward the outer side with said microcrystal grains as nuclei so that polycrystal grains greater than said microcrystal grains are produced in the area of said external region adjacent to said boundary; and a fourth process in which heat is transferred from said heated light absorbing layer to said semiconductor thin film through said gate insulation film, whereby said internal region is melted, and thereafter a second lateral growth progresses from said boundary toward the inner side with said polycrystal grains as nuclei so that further enlarged polycrystal grains are produced in said internal region.

9. The thin film semiconductor device as set forth in claim 8, wherein said light absorbing layer used in said laser annealing is comprised of a conductive material, and said gate electrode is formed from said conductive material either directly or through a processing.

10. The thin film semiconductor device as set forth in claim 9, wherein said gate electrodes is formed by using a high melting point metal or an alloy or silicide containing a high melting point metal as a constituent thereof, as said conductive material.

11. The thin film semiconductor device as set forth in claim 7, wherein said source region and said drain region range into at least a part of said first lateral growth region.

12. The thin film semiconductor device as set forth in claim 7, wherein said first lateral growth region in which said source region and said drain region are formed ranges over a distance of at least 2 μm from said boundary toward the outer side.

13. The thin film semiconductor device as set forth in claim 7, wherein said thin film transistor comprises an LDD region lower in impurity concentration than said drain region between said channel region and at least said drain region, and said LDD region is formed in said first lateral growth region or said second lateral growth region.

14. A display comprising an insulating substrate provided integratedly with pixels and thin film transistors for driving said pixels, wherein
each said thin film transistor comprises a semiconductor thin film and a gate electrode laminated, with a gate insulation film therebetween;
said semiconductor thin film comprises a channel region overlapping with said gate electrode, and a source region and a drain region which are located respectively on both sides of said channel region;
said semiconductor thin film is a polycrystalline layer crystallized by laser annealing, and is divided along the boundary of a predetermined pattern into an internal region and an external region;
said external region has a first lateral growth region containing polycrystal grains laterally grown from said boundary toward the outer side by said laser annealing;
said internal region has a second lateral growth region containing polycrystal grains laterally grown from said boundary toward the inner side with said polycrystal grains contained in said first lateral growth region as nuclei; and
said channel region is formed in said second lateral growth region.

15. The display as set forth in claim 14, wherein said semiconductor thin film is a polycrystalline layer crystallized by said laser annealing conducted by irradiation with laser light through a light absorbing layer formed in a predetermined pattern, and is formed through: a first process in which said external region located on the outer side relative to the pattern of said light absorbing layer is thermally melted, and said light absorbing layer is heated, without melting said internal region located on the inner side relative to the pattern of said light absorbing layer; a second process in which said molten semiconductor thin film is cooled and microcrystal grains are produced in the vicinity of said boundary between said external region and said internal region; a third process in which a first lateral growth progresses from said boundary between said external region and said internal region toward the outer side with said microcrystal grains as nuclei so that polycrystal grains greater than said microcrystal grains are produced in the area of said external region adjacent to said boundary; and a fourth process in which heat is transferred from said heated light absorbing layer to said semiconductor thin film through said gate insulation film, whereby said internal region is melted, and thereafter a second lateral growth progresses from said boundary toward the inner side with said polycrystal grains as nuclei so that further enlarged polycrystal grains are produced in said internal region.

16. The display as set forth in claim 14, wherein each said pixel comprises an organic electroluminescence device.

17. The display as set forth in claim 14, wherein each said pixel comprises a pixel electrode connected to said thin film transistor, a counter electrode opposed to said pixel electrode, and a liquid crystal held between said electrodes.
